(19) United States
(12) Patent Application Publication
(10) Pub. No.: US 2006/0086940 A1
(43) Pub. Date: Apr. 27, 2006

(54) Package structure of multi-chips light-emitting module

(76) Inventors: Jim Wang, Hukou Shiang (TW); Ben H. Chiang, Hukou Shiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/972,377

(22) Filed: Oct. 26, 2004

(51) Int. Cl. H01L 33/00

(52) U.S. Cl. 257/79; 257/99; 257/98

(57) ABSTRACT

The present invention pertains to a package structure of multi-chips light-emitting module, wherein via the packaging technology of semiconductor, a plurality of light emitting diode chips are installed on the disposing portion of a lead frame, and the chips and the lead frame are interconnected with bond wires, and then an encapsulant is used to cover the chips, bond wires and the disposing portion to form a package structure. The light-emitting module packaged with the structure having the disposing portion can be applied to the light source of lightening, indicator and alarm, etc., and not only has high light permeability, but also has the function of diverging as well as focusing the light source.

### BACKGROUND OF THE INVENTION

(a) Field of the Invention

The present invention relates to a package structure of light-emitting module, particularly to an improved package structure of multi-chips light-emitting module.

(b) Description of Related Art

The light emitting diode (LED) is a semiconductor element, and has the characteristics of small size, long lifespan and low power consumption. Therefore, LED is generally utilized in indication and display devices, and the application territory thereof includes backlight source of a mobile phone, indication light of consumptive electronic products, industrial instrument, instrument panel light and brake light of an automobile, spectacular advertising display, and traffic signal light.

Referring to FIG. 1a and FIG. 1b, a conventional light 2 is usually assembled from encapsulated single-chip LED light-emitting module 4s with soldering. As the encapsulated single-chip LED light-emitting module 4, wherein one package thereof has only one LED chip inside, is adopted in the conventional light 2, numerous electronic elements of encapsulated single-chip LED 4s are needed in one light 2. Consequently, the yield rate of manufacturing and the reliability of product will be reduced, and the cost and time of packaging will be raised. The objective of the present invention is to provide an improved structure to solve the aforementioned problems.

### SUMMARY OF THE INVENTION

The primary objective of the present invention is to provide a package structure of multi-chips light-emitting module, wherein at least one disposing portion is formed on the lead frame, and a plurality of chips can be installed inside the disposing portion.

Another objective of the present invention is to provide a package structure of multi-chips light-emitting module, wherein a plurality of chips inside the disposing portion are covered with a fluorescent resin, and the fluorescent resin is formed into a convex lens shape in order to achieve a light diverging effect.

Yet another objective of the present invention is to provide a package structure of multi-chips light-emitting module in order to increase the lifespan of the light-emitting module.

According to one aspect of the present invention, the package structure of multi-chips light-emitting module of the present invention comprises:
a lead frame;
a disposing portion, which is formed on the lead frame;
a plurality of chips, which are installed on the disposing portion;
at least two bond wires, which are used to electrically interconnect the chip and the lead frame via a wire-bonding method; and
a transparent resin, which covers the disposing portion, chips, and bond wires, and forms an upper covering layer above the lead frame and a lower covering layer below the lead frame.

The preferred embodiments of the present invention will be described below in detail in co-operation with the attached drawings in order to enable the objectives, technical contents, characteristics and accomplishments to be more easily understood.

### BRIEF DESCRIPTION OF THE DRAWINGS

FIG. 1a is a top view of the conventional light.

FIG. 1b is a schematic diagram of the package structure of a conventional single-chip light-emitting module.

FIG. 2a is a top view of the lead frame according to one aspect of the present invention.

FIG. 2b is a side view of the lead frame according to one aspect of the present invention.

FIG. 3a is a diagram illustrating the ellipse curve according to a formula of ellipse.

FIG. 3b is a diagram illustrating that the bottom of the disposing portion is positioned at the focus of the ellipse curve.

FIG. 3c is a diagram illustrating the tilt angle of the disposing portion wall.

FIG. 4a is a sectional view of the disposing portion contains four chips.

FIG. 4b is a sectional view of the disposing portion contains eight chips.

FIG. 4c is a sectional view of the disposing portion contains twelve chips.

FIG. 4d is a sectional view of the disposing portion contains sixteen chips.

FIG. 4a-1 is a top view of the disposing portion contains four chips.

FIG. 4b-1 is a top view of the disposing portion contains eight chips.

FIG. 4c-1 is a top view of the disposing portion contains twelve chips.

FIG. 4d-1 is a top view of the disposing portion contains sixteen chips.

FIG. 5a is a schematic diagram of the dual in-line package structure of the multi-chips light-emitting module according to a first embodiment of the present invention.

FIG. 5b is a schematic diagram of the small outline package structure of the multi-chips light-emitting module according to a first embodiment of the present invention.

FIG. 6a is a diagram illustrating that the chip and the lead frame are interconnected via one chip-one point method.

FIG. 6b is a diagram illustrating that the chip and the lead frame are interconnected via multi chips-one point method.

FIG. 7a is a schematic diagram of the dual in-line package structure of the multi-chips light-emitting module according to a second embodiment of the present invention.

FIG. 7b is a schematic diagram of the small outline package structure of the multi-chips light-emitting module according to a second embodiment of the present invention.

FIG. 8a is a schematic diagram of the dual in-line package structure of the multi-chips light-emitting module according to a third embodiment of the present invention.

FIG. 8b is a schematic diagram of the small outline package structure of multi-chips light-emitting module according to a third embodiment of present invention.

FIG. 9 is a diagram illustrating the area comparison between the conventional light and the assemblage of the multi-chips light-emitting modules of the present invention.

### LIST OF REFERENCE NUMERALS

2 conventional light
4 single-chip LED light-emitting module
10 lead frame
12 disposing portion
a half of the length of the major axis of the ellipse
b half of the length of the minor axis of the ellipse
c focal length of the ellipse
F focus of the ellipse
θ tilt angle of the disposing portion wall
14 plane shape
16 chip
17 center of the disposing portion
18 concave shape
20 bond wires
22 transparent resin
222 upper covering layer
224 lower covering layer
24 fluorescent resin
26 convex-lens shape
28 back portion of the disposing portion
30 convex shape
32 arc shape

### DESCRIPTION OF THE PREFERRED EMBODIMENTS OF THE PRESENT INVENTION

The present invention is to provide a package structure of multi-chips light-emitting module, which has high permeability of light, and possesses functions of diverging as well as focusing the light source.

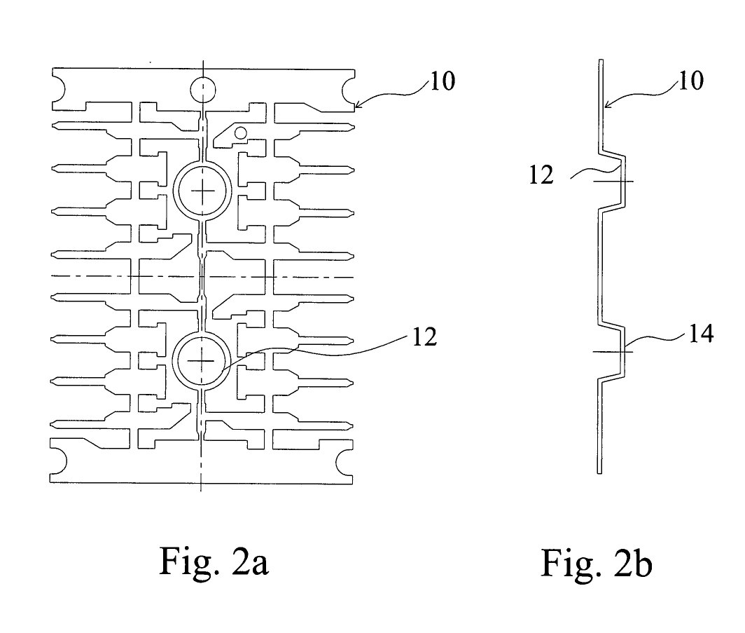

Referring to FIGS. 2a and 2b the top and side views of the lead frame according to one aspect of the present invention, the lead frame 10, which is made of a metallic material, comprises at least a disposing portion 12, which is formed into a basin of concave shape in this aspect of the present invention and has a bottom of a plane shape 14.

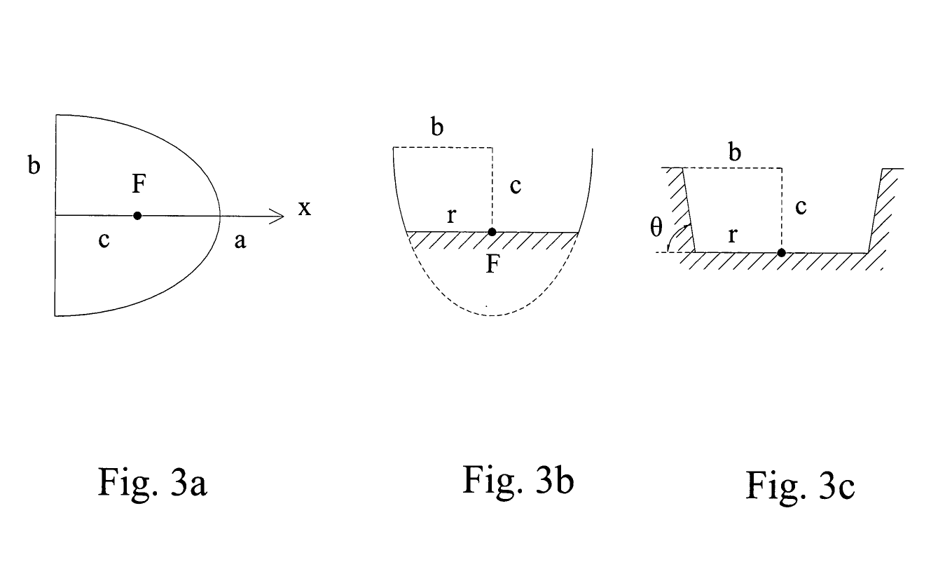

Referring to FIG. 3a, the depth of the disposing portion is calculated from the elliptic formula x²/a²+y²/b²=1 and the formula a²=b²+c², wherein a is half of the length of the major axis of the ellipse, and b is half of the length of the minor axis of the ellipse, and c is the focal length of the ellipse, and F is the focus of the ellipse. Referring to FIG. 3b, the disposing portion is positioned at the focus F, and the radius of the disposing portion is r, and c represents the depth of the disposing portion, and b represents half of the width of the disposing portion. Referring to FIG. 3c, the tilt angle of the disposing portion wall is calculated from the formulaθ=tan⁻¹ [c/(b−r)].

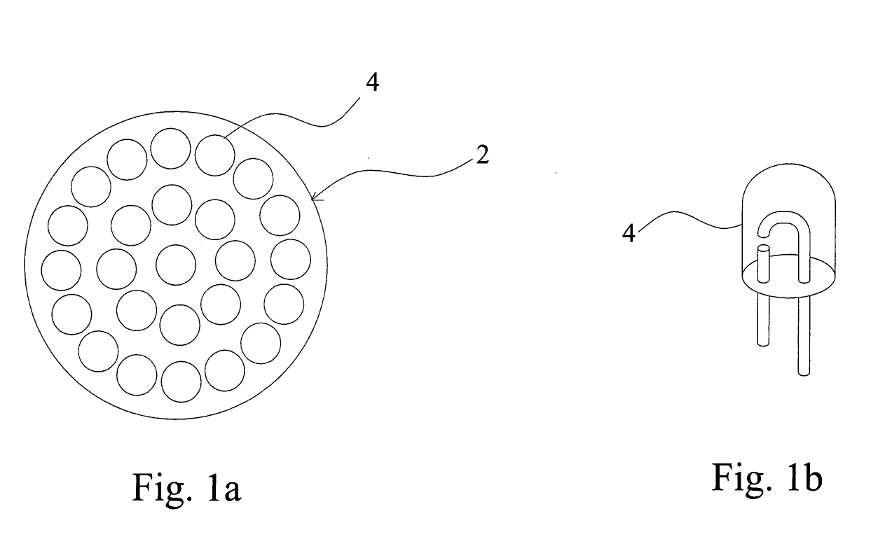

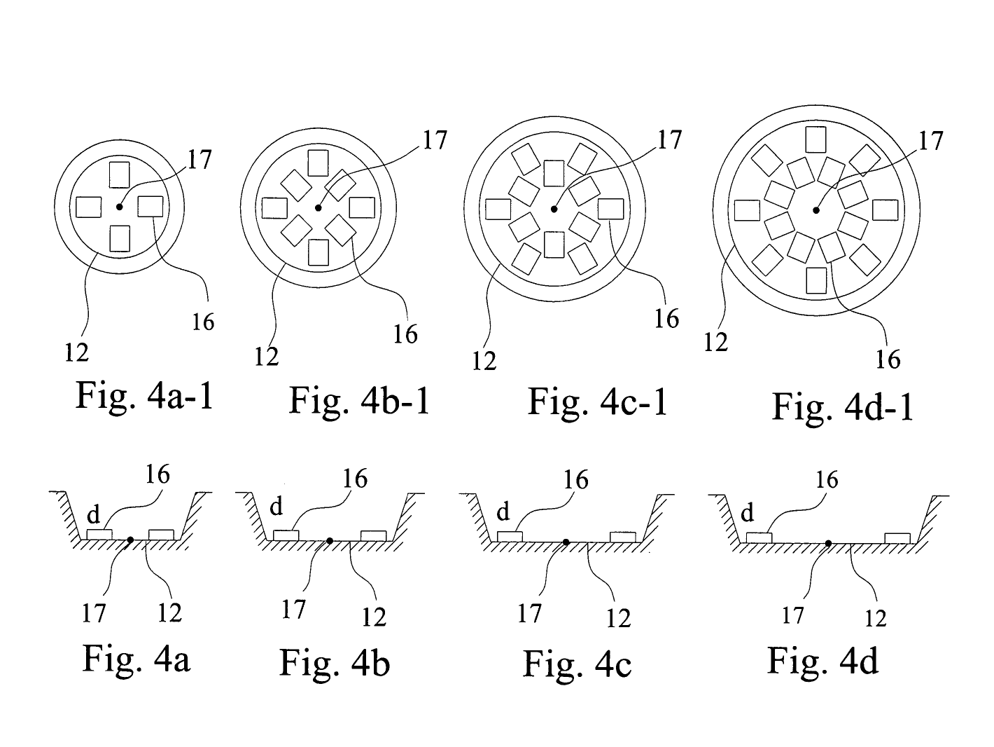

FIG. 4a, 4b, 4c, 4d are the sectional views and FIG. 4a-1, 4b-1, 4c-1, 4d-1 are the top views separately illustrating that the disposing portion contains four, eight, twelve, or sixteen chips. The dimension of the chip 16 is about 15×12 mils (one thousandth of an inch), and the dimensional relation between the disposing portion 12 and the chip 16 is that r=2d, r=2.5d, r=3d, r=3.5d separately. The chips 16 adhere to the bottom of the disposing portion 12 with an electrically conductive paste. The distribution of the chips 16 on the bottom of the disposing portion 12 is arranged according to the geometry of the disposing portion 12, and the number of the chips that can be contained in the disposing portion 12 depends on the size of the disposing portion 12. The center 17 of the disposing portion 12 is a point of virtual light source, and the light emitted from the chips 16 is focused at the point of virtual light source, and the light emitted from the center 17 can form a highly efficient light source.

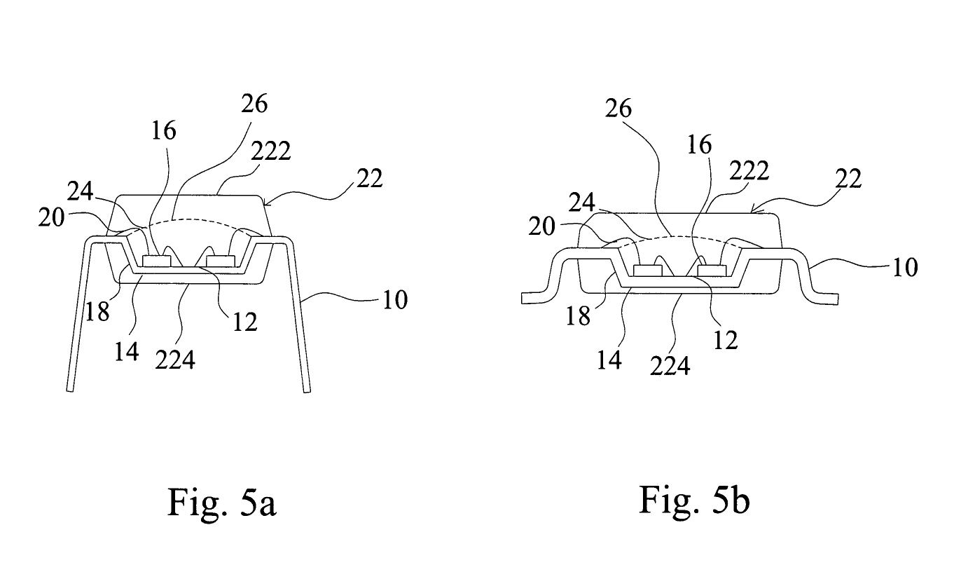

Referring to FIGS. 5a and 5b schematic diagrams separately of the dual in-line package (DIP) structure and the small outline package (SOP) structure of the multi-chips light-emitting module according to a first embodiment of the present invention, a concave shape 18 is formed on the lead frame 10 as the disposing portion 12, and a light-reflecting area is formed inside the disposing portion 12. The light-reflecting area includes the inner wall and the bottom of the disposing portion 12 and is formed via electroplating an electrically conductive and light-reflecting metal thereon. The inner wall and bottom is formed into a shape of concave-mirror in order to focus the light. A plurality of chips 16 are installed on the bottom of the disposing portion 12, and at least two bond wires 20 are used to electrically interconnect the chips 16 and the lead frame 10 via a wire-bonding method. A transparent resin 22, which can be an epoxy resin, covers the disposing portion 12 of the lead frame 10, chips 16, and bond wires 20, and forms an upper covering layer 222 and a lower covering layer 224, which have flat surfaces and possess a protective function.

In order to enable the light-emitting module to emit the white light, a fluorescent resin 24 is further utilized to cover the disposing portion 12, and also encapsulate the chips 16 and the bond wires 20 to form a convex-lens shape 26 which has a diverging function of the light source.

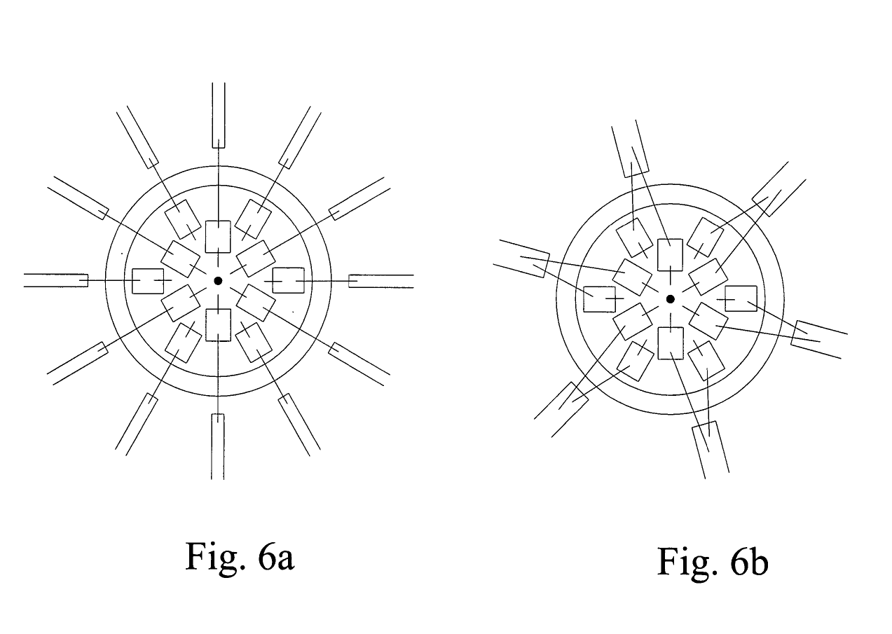

Referring to FIGS. 6a and 6b, the interconnecting method of the lead frame 10 and the chips 16 can adopt a “one chip-one point” method or a “multi chips-one point” method. If the “multi chips-one point” method is adopted, the yield rate of manufacturing and the reliability of the product will be raised because the number of the lead frame is decreased.

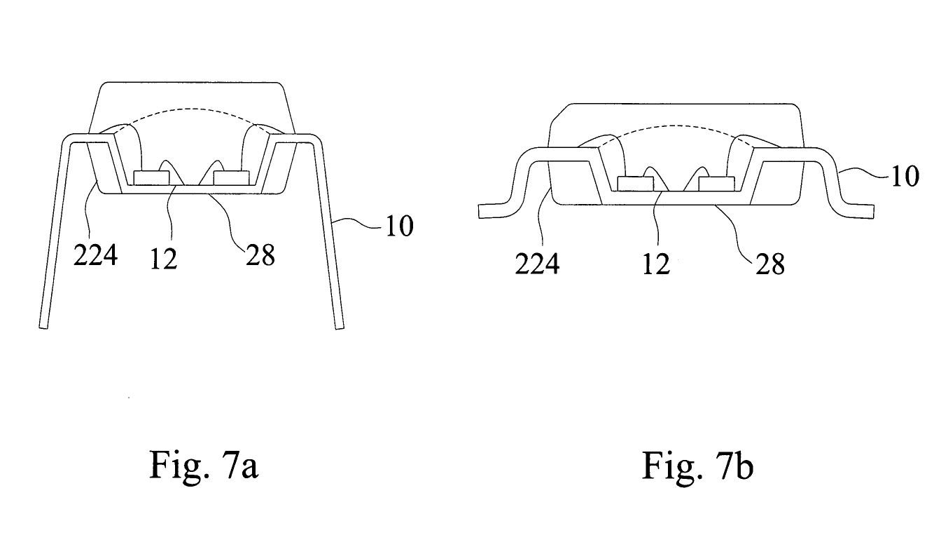

Referring to FIGS. 7a and 7b schematic diagrams separately of the dual in-line package (DIP) structure and the small outline package (SOP) structure of the multi-chips light-emitting module according to a second embodiment of the present invention, a naked-back package structure is adopted in the second embodiment. The difference between the first and the second embodiments is the lower covering layer 224. In the second embodiment, the lower covering layer 224 only covers the lateral potion of the disposing portion 12 of the lead frame 10 and leaves the back portion 28 naked in order to achieve a better heat-dissipating effect. The rest of the structure of the second embodiment is the same as that of the first embodiment.

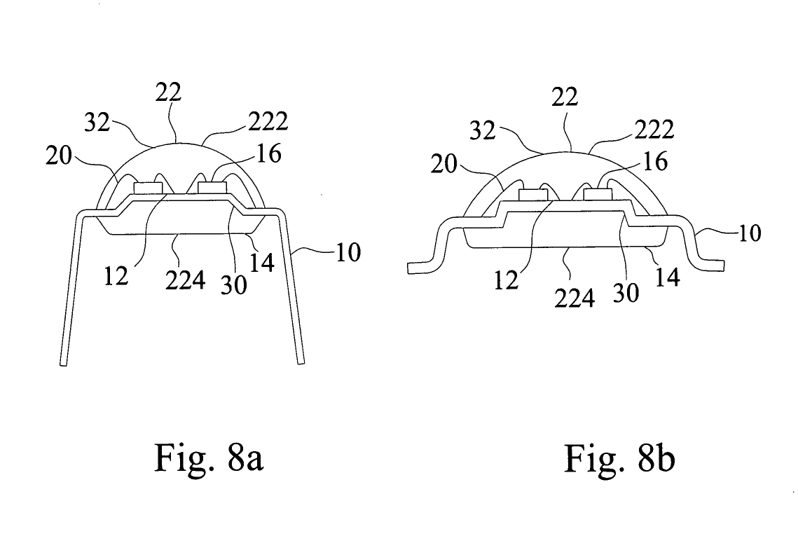

Referring to FIGS. 8a and 8b schematic diagrams separately of the dual in-line package (DIP) structure and the small outline package (SOP) structure of the multi-chips light-emitting module according to a third embodiment of the present invention, the third embodiment adopts a wide-angle-divergence package structure. A disposing porting 12 of a convex shape 30 is formed on the lead frame 10. Aplurality of chips 16 is installed on the surface of the disposing portion 12. The chips 16 and the lead frame 10 are electrically interconnected with bond wires 20 via a wire-bonding method. A transparent resin 22, which can be an epoxy resin, covers the disposing portion 12 of the lead frame 10, the chips 16 and the bond wires 20 to form an upper covering layer 222 and a lower covering layer 224. The upper covering layer 222 is of an arc shape 32 that has a wide-angle-divergence effect, and the lower covering layer 224 is of a plane 14. The upper and lower covering layers 222 and 224 have a protective function.

Each of the aforementioned first, second and third embodiments has two types of products, i.e. the dual in-line package (DIP) structure and the small outline package (SOP) structure; the width of the DIP product ranges from three hundred to six hundred thousandths of an inch; the width of the SOP product ranges from one hundred and fifty to three hundred thousandths of an inch.

In summary, owing to the concave-mirror shape of the inner wall of the disposing portion of the present invention, the light emitted from the chips can be focused at the center of the disposing portion. As the present invention further comprises the fluorescent resin covering the disposing portion and encapsulating the chips and bond wires to form a convex-lens shape, the light focused at the center of the disposing portion can be emitted out divergently via the convex-lens shape. In co-operation with a transparent resin, which forms an external upper and lower covering layers, the present invention possesses a characteristics of high light permeability.

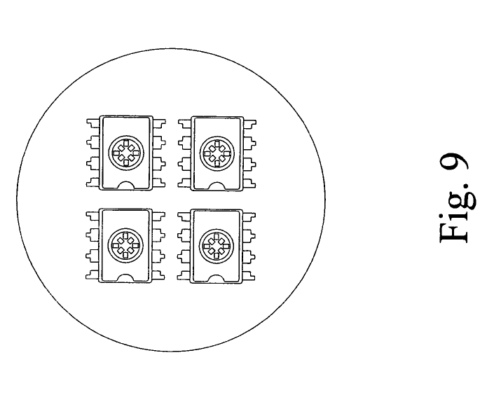

Via a disposing portion on the lead frame of the multi-chips light-emitting module of the present invention, the disposing portion can contain a plurality of chips; therefore, via the packaging process of semiconductor, a plurality of chips can be packaged in a single packaging process, and thus the material and time used in the packaging can be reduced in contrast to the conventional package structure of the single-chip light-emitting module. Referring to FIG. 9, the area of the light utilizing the conventional single-chip light-emitting module is several times that of the assemblage of the multi-chips light-emitting modules, and thus the present invention can achieve a smaller area.

Owing to the adoption of the multi-chips light-emitting module in the package structure of the present invention, when one of the chips is out of order, the product of the present invention can still continue to work; accordingly, the lifespan of the product of the present invention is longer than the conventional.

Via the aforementioned statement, it can be concluded that the product according to the present invention is superior to that of the conventional in cost, yield rate, reliability and size.

What is claimed is:

1. A package structure of multi-chips light-emitting module, comprising:
a lead frame, whereon at least a disposing portion is installed with a light-reflecting area installed inside said disposing portion;
a plurality of chips, installed on said disposing portion;
at least two bond wires, interconnecting said chips and said lead frame via a wire-bonding method; and
a transparent resin, covering said disposing portion of said lead frame, said chips, and said bond wires to form an upper covering layer above said lead frame and a lower covering layer below said lead frame.

2. The package structure of multi-chips light-emitting module according to claim 1, wherein the inner wall of said disposing portion is of a concave-mirror shape.

3. The package structure of multi-chips light-emitting module according to claim 1, further comprising a fluorescent resin, which covers said disposing portion and also encapsulates said chips and said bond wires to form a convex-lens shape.

4. The package structure of multi-chips light-emitting module according to claim 1, wherein said chips are installed on the bottom of said disposing portion and arranged according to the geometry of said disposing portion.

5. The package structure of multi-chips light-emitting module according to claim 1, wherein said chips adhere fixedly to said bottom of said disposing portion via an electrically conductive paste.

6. The package structure of multi-chips light-emitting module according to claim 1, wherein said bottom of said disposing portion is of a plane shape.

7. The package structure of multi-chips light-emitting module according to claim 1, wherein said lead frame is made of a metallic material.

8. The package structure of multi-chips light-emitting module according to claim 1, wherein said transparent resin is an epoxy.

9. The package structure of multi-chips light-emitting module according to claim 1, wherein said disposing portion of said lead frame is of a concave shape, and said chips are installed on the inner bottom face of said disposing portion.

10. The package structure of multi-chips light-emitting module according to claim 1, wherein said disposing portion on said lead frame is of a convex shape, and said chips are installed on the surface of said disposing portion.

11. The package structure of multi-chips light-emitting module according to claim 9, wherein said disposing portion of said lead frame is of a concave shape, and said upper covering layer is of a plane shape.

12. The package structure of multi-chips light-emitting module according to claim 9, wherein said disposing portion of said lead frame is of a concave shape, and said lower covering layer is of a plane shape, or said lower covering layer covers only the lateral portion of said disposing portion and leaves the back surface of said disposing portion naked.

13. The package structure of multi-chips light-emitting module according to claim 10, wherein said disposing portion on said lead frame is of a convex shape, and said upper covering layer is of a arc shape, and said lower covering layer is of a plane shape.

14. The package structure of multi-chips light-emitting module according to claim 1, wherein a single chip-one point or a multi chips-one point connecting method is adopted as the interconnecting method between said lead frame and said chips.

15. The package structure of multi-chips light-emitting module according to claim 1, whose products include a dual in-line package (DIP) type and a small outline package (SOP) type of products.

16. The package structure of multi-chips light-emitting module according to claim 1, wherein said light-reflecting area is the inner wall and bottom face of said disposing portion and is formed via electroplating an electrically conductive and light-reflecting metal thereupon.
